(19) United States
(12) Patent Application Publication
(10) Pub. No.: US 2018/0337217 A1
(43) Pub. Date: Nov. 22, 2018

(54) DISPLAY SUBSTRATE, DISPLAY PANEL, AND DISPLAY APPARATUS

(71) Applicants: BOE TECHNOLOGY GROUP CO., LTD., Beijing (CN); CHENGDU BOE OPTOELECTRONICS TECHNOLOGY CO., LTD., Chengdu, Sichuan (CN)

(72) Inventors: Pengcheng ZANG, Beijing (CN); Yang WANG, Beijing (CN); Ting LI, Beijing (CN)

(73) Assignees: BOE TECHNOLOGY GROUP CO., LTD., Beijing (CN); CHENGDU BOE OPTOELECTRONICS TECHNOLOGY CO., LTD., Chengdu, Sichuan (CN)

(21) Appl. No.: 15/518,761

(22) PCT Filed: Jul. 1, 2016
(86) PCT No.: PCT/CN2016/088172

§ 371 Date: Apr. 12, 2017

(30) Foreign Application Priority Data
Feb. 2, 2016 (CN) 201610074558.3

(51) Int. Cl. H01L 27/32; H01L 51/00; H01L 51/52

(52) U.S. Cl. CPC H01L 27/322; H01L 51/5281; H01L 51/0096

(57) ABSTRACT

This disclosure provides a display substrate, a display panel, and a display apparatus, aiming to solve the issue of appearance of zigzag, and of the color difference among pixels, at the edge of display panels. The display substrate comprises a display region, and the display region has an irregular edge portion including a plurality of edge pixel units, adjacent to a light-shielding region; and the plurality of edge pixel units have gradually varying light transmission rates along the irregular edge portion.

### CROSS-REFERENCE TO RELATED APPLICATION

The present application claims priority to Chinese Patent Application No. 201610074558.3 filed on Feb. 2, 2016, the disclosure of which is hereby incorporated by reference in its entirety.

### TECHNICAL FIELD

This disclosure relates generally to the field of display technology, and more specifically to a display substrate, a display panel, and a display apparatus.

### BACKGROUND

With the rapid development of display technologies, there has been an increasingly high demands for display panels to adapt to different surroundings, which has prompted the emergence of display panels with specialty designs. These display panels can have non-rectangular shapes, such as circular, semicircular, octagon, or other desired shapes. Some of the specialty display panels can be modified on the basis of conventional rectangular display panels, and configured to better adapt to the overall structure and environment of the buildings in which they are disposed. Currently, common display panels with special shapes may include fan-shaped, curved, circular, cylindrical, and triangular shaped display panels.

### SUMMARY

This disclosure provides a display substrate, a display panel, and a display apparatus, aiming to solve the issue of appearance of zigzag, and of the color difference among pixels, at the edge of display panels.

In an aspect, the disclosure provides a display substrate, which comprises a display region. The display region has an irregular edge portion including a plurality of edge pixel units, adjacent to a light-shielding region; and the plurality of edge pixel units have gradually varying light transmission rates along the irregular edge portion.

In some embodiments of the display substrate, the display region is provided with a pixel unit array, comprising a plurality of pixel units arranged in rows and columns, wherein each pixel unit comprises at least one pixel. The irregular edge portion of the display region can comprise at least one protruding region, and each of the at least one protruding region can comprise a second plurality of edge pixel units. The second plurality of edge pixel units are consecutively aligned in a same row or a same column of the pixel unit array, and have gradually varying light transmission rates along the each of the at least one protruding region to thereby reduce a zigzag pattern.

In some of the embodiments, the second plurality of edge pixel units can have gradually varying opening ratios to realize the gradually varying light transmission rates along the each of the at least one protruding region.

The opening ratios for different pixels of different colors can be substantially same within each of the second plurality of edge pixel unit in the each of the at least one protruding region.

The gradually varying opening ratios for the second plurality of edge pixel units in the each of the at least one protruding region can be realized by configuring at least two transition sub-steps between a light-emitting sub-region of the each of the at least one protruding region and the light-shielding region. The at least two transition sub-steps each has a substantially same ascending direction as a protruding step formed between the each of the at least one protruding region and the light-shielding region.

The light-shielding region can include at least one light-shielding pattern, which is disposed over each of the at least one protruding region and is configured to form the at least two transition sub-steps in the each of the at least one protruding region.

The second plurality of edge pixel units in each of the at least one protruding region can correspond to the at least two transition sub-steps in a one-to-one relationship.

Any two neighboring edge pixel units in each of the at least one protruding region can have a substantially same difference in light-emitting area.

In some embodiments, the at least one light-shielding pattern comprises two light-shielding patterns, and the two light-shielding patterns are disposed in a same layer.

In some other embodiments, one of the at least one light-shielding pattern can comprise a plurality of light-shielding sub-patterns, corresponding to pixels in each of the second plurality of edge pixel units in a one-to-one relationship.

In some of the above embodiments, each pixel can have a rectangular shape, and each of the plurality of light-shielding sub-patterns can be rectangular.

In some of the above embodiments, an intersection line between each of the plurality of light-shielding sub-patterns and corresponding pixel has a substantially same ascending direction as the protruding step. Each of the intersection lines between the plurality of light-shielding sub-patterns and corresponding pixels can be a straight line or a curved line.

In some of the above embodiments, each pixel can have a rectangular shape, each of the plurality of light-shielding sub-patterns can have a shape of a right trapezoid, and a slanted leg of the right trapezoid can be aligned with the straight line.

In some of the above embodiments, each of the intersection lines is parallel with one another.

The display substrate as described above can be a color film substrate, a color filter on array (COA) substrate, or an OLED substrate. The at least one light-shielding pattern can be disposed at a same layer as a black matrix in the color film substrate or the color filter on array (COA) substrate.

In another aspect, the present disclosure provides a display panel, which comprises the display substrate according to any of the above mentioned embodiments.

In yet another aspect, the disclosure provides a display apparatus, which includes the display panel as described above.

Other embodiments and implementations may become apparent in view of the following description and drawings.

### BRIEF DESCRIPTION OF DRAWINGS

To more clearly illustrate some of the embodiments, the following is a brief description of the drawings. The drawings in the following descriptions are only illustrative of some embodiments. For those of ordinary skill in the art, other drawings of other embodiments can become apparent based on these drawings.

FIG. 1 is a schematic diagram of a conventional special-shaped display panel.

FIG. 2 is a schematic diagram of a special-shaped display panel according to some embodiments of the disclosure.

FIG. 3 is a schematic diagram of a protruding region formed by a same row of multiple consecutively aligned edge pixel units in a conventional special-shaped display panel.

FIG. 4 is a schematic diagram of a protruding region after improvement over the protruding region as shown in FIG. 3 by means of a first embodiment of the disclosure.

FIG. 5 is a schematic diagram of a protruding region after improvement over the protruding region as shown in FIG. 3 by means of a second embodiment of the disclosure.

FIG. 6 is a schematic diagram of a protruding region after improvement over the protruding region as shown in FIG. 3 by means of a third embodiment of the disclosure.

FIG. 7 is a schematic diagram of a protruding region formed by a same column of multiple consecutively aligned edge pixel units in a conventional special-shaped display panel.

FIG. 8 is a schematic diagram of a protruding region after improvement over the protruding region as shown in FIG. 7 by means of a first embodiment of the disclosure.

FIG. 9 is a schematic diagram of a protruding region after improvement over the protruding region as shown in FIG. 7 by means of a second embodiment of the disclosure.

FIG. 10 is a schematic diagram of a protruding region after improvement over the protruding region as shown in FIG. 7 by means of a third embodiment of the disclosure.

### DETAILED DESCRIPTION

In the following, with reference to the drawings of various embodiments disclosed herein, the technical solutions of the embodiments of the disclosure will be described in a clear and fully understandable way. It is noted that the described embodiments are merely a portion but not all of the embodiments of the disclosure. Based on the described embodiments of the disclosure, those ordinarily skilled in the art can obtain other embodiment(s), which come(s) within the scope sought for protection by the disclosure.

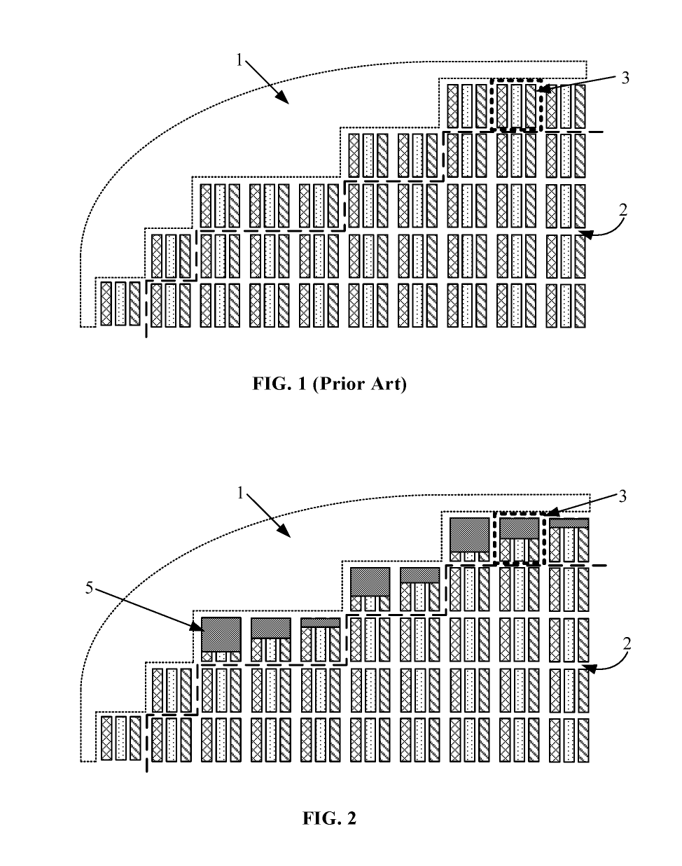

FIG. 1 is the schematic diagram of a conventional special-shaped display panel. As shown in FIG. 1, the display panel comprises a display region 2 and a light shielding region 1, arranged at the periphery of the display area 2. The display region 2 is provided with a pixel unit array comprising a plurality of pixel units. The outermost pixel units of the pixel unit array that are also adjacent to the light-shielding region 1 are edge pixel units 3.

In conventional pixel units, pixels are typically rectangular in shape, and thus in forming the edge of a special-shaped (with curved or oblique edge) display panel, the pixels of a same size in edge pixel units need to be arranged in a zigzag. When displaying, a difference in brightness exists between these edge pixel units and the light shielding region, which causes the edge of the display panel to exhibit a zigzag pattern.

Especially for multiple consecutive edge pixel units aligned in a same row or a same column, a ladder-shape appearance typically shows up between the row/column of pixel units and adjacent row/column of pixel units, i.e. a zigzag edge exhibits on the display panel, thereby resulting in a reduced visual effect on the edge of the display panel, and seriously influencing the user experience.

To solve this issue, this disclosure provides a display substrate. The display substrate includes a display region, which has an irregular edge portion including a plurality of edge pixel units. The plurality of edge pixel units have gradually varying light transmission rates along the edge portion to thereby reduce the zigzag pattern. To this end, the open ratios of the edge pixel units at the irregular edge portion of the display region can be altered, or alternatively each of the edge pixel units may be configured to have varying light transmission rate by itself while remaining a same open ratio. In this disclosure, it is mainly realized by altering the open ratios of the edge pixel units.

In some embodiments, the display region is provided with a pixel unit array, comprising a plurality of pixel units arranged in rows and columns, wherein each pixel unit comprises at least one pixel. The irregular edge portion of the display region comprises at least one protruding region, each of the at least one protruding region comprising a second plurality of edge pixel units. The second plurality of edge pixel units are consecutively aligned in a same row or a same column of the pixel unit array, and have gradually varying light transmission rates along the each of the at least one protruding region to thereby reduce a zigzag pattern.

FIG. 2 is a schematic diagram of a special-shaped display panel according to some embodiments of the disclosure. As shown in FIG. 2, the display panel comprises a display region 2 and a light-shielding region 1, wherein the light-shielding region 1 is at the periphery of the display region 2. The display region 2 is provided with a pixel unit array, which comprises a plurality of pixel units. The pixel units at the outermost of the pixel unit array that are adjacent to the light-shielding region 1 are edge pixel units 3.

A plurality of consecutive edge pixel units aligned at a same row or at a same column form a protruding region; a protruding step forms at the intersection between a protruding region and the light-shielding region 1; the protruding region comprises a first light-shielding pattern 5, configured such that at least two transition sub-steps are formed at the intersection between the light-emitting sub-region of the protruding region and the first light-shielding pattern 5. The at least two transition sub-steps and the corresponding protruding step have a substantially same ascending direction.

It is noted that a step corresponds to a folded segment, which has only one turning point, and includes at least one horizontal segment or a longitudinal segment. The ascending direction in the disclosure can specifically include two scenarios, i.e. a first ascending direction and a second ascending direction, wherein the first ascending direction includes any direction between a first horizontal direction and a vertical upward direction, and the second ascending direction includes any direction between a second horizontal direction and a vertical upward direction.

In current technologies, the plurality of consecutive edge pixel units aligned at a same row or at a same column typically form a protruding step with a relatively big size, which easily results in the appearance of zigzags. In the embodiment disclosed herein, by arranging a first light-shielding pattern 5 in the protruding region, the relatively big protruding step is transformed into multiple relatively small transition sub-steps having a substantially same ascending direction as the protruding step. These relatively small transition sub-steps result in less apparent zigzags, which in turn weakens the overall appearance of zigzags at the protruding region while displaying, ultimately leading to an improved visual effect at the edge of the display panel.

One embodiment is provided herein. For convenience, a first ascending direction is the leftward ascending direction (i.e. pointing to upper left) in figures, and a second ascending direction is the rightward ascending direction (i.e. pointing to upper right) in the figures.

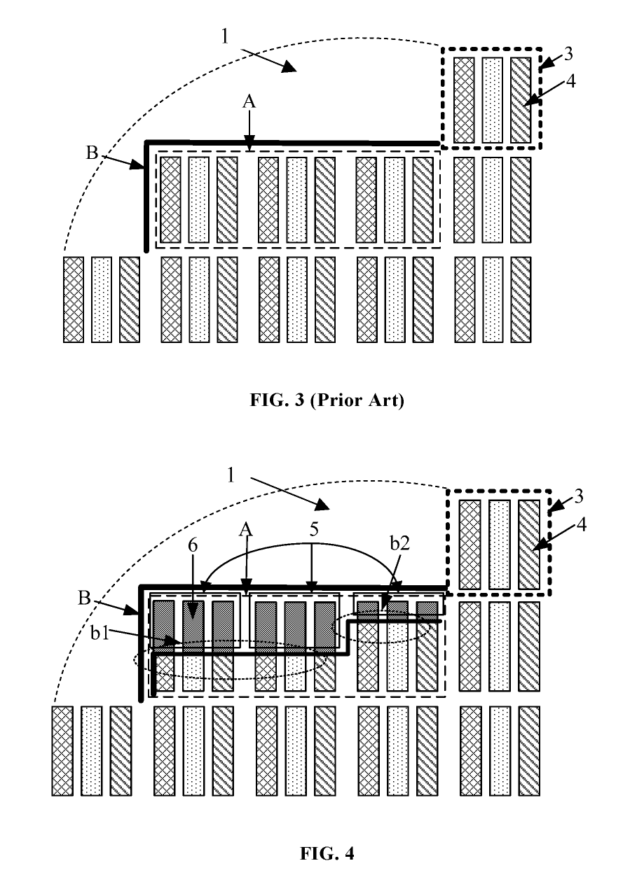

FIG. 3 is a schematic diagram of a protruding region formed by a same row of multiple consecutively aligned edge pixel units in conventional special-shaped display panels. As shown in FIG. 3, the three consecutive edge pixel units aligned at a same row form a protruding region A; a protruding step B is formed between the protruding region A and the light-shielding region 1; and the protruding step B has a rightward ascending direction.

FIG. 4 is a schematic diagram of a protruding region after improvement over the protruding region as shown in FIG. 3 by means of a first embodiment of the disclosure. As shown in FIG. 4, by arranging a first light-shielding pattern 5 in the protruding region A, two transition sub-steps b1 and b2 are formed at the intersection between the light-emitting sub-region of the protruding region A and the first light-shielding pattern 5; and the two transition sub-steps b1 and b2 both have a rightward ascending direction.

Compared with the protruding step B, the two transition sub-steps b1 and b2 are relatively smaller in size and are thus less obvious. Additionally because the two transition sub-steps b1 and b2 both have right ascending directions, the transition among different sub-steps appear relatively smooth, and the overall appearance of zigzags at the protruding region are thus weakened, which ultimately leads to an improved visual effect at the protruding region A. Consequently for the overall display panel, the visual effect at the edge of the display panel is improved.

Optionally the first light-shielding pattern 5 can include a plurality of light-shielding sub-patterns 6, which correspond to the pixels 4 included in each of the edge pixel units 3 in a one-to-one relationship and are configured to define the light-emitting sub-region of the corresponding pixels 4.

When the first light-shielding pattern 5 is configured to shield the edge pixel units 3, the pixels 4 in the edge pixel units 3 can optionally be configured to have a same area of light-emitting sub-region, thereby effectively avoiding the issue of color difference among different edge pixel units.

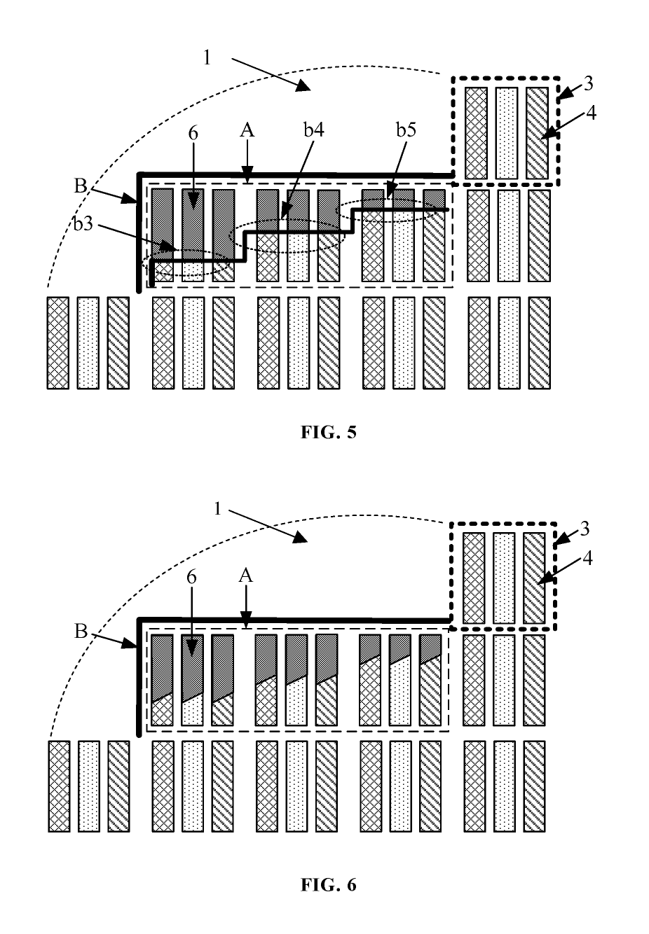

FIG. 5 is a schematic diagram of a protruding region after improvement over the protruding region as shown in FIG. 3 by means of a second embodiment of the disclosure. Compared with the first embodiment as shown in FIG. 4, transition sub-steps b3, b4 and b5 are configured to have a same number as edge pixel units 3 in the protruding region A, and to correspond to the edge pixel units in a one-to-one relationship, as shown in FIG. 5.

By this configuration, the transition sub-steps b3, b4, and b5 in the protruding region A have an even smaller size, thus resulting in a further weakened appearance of zigzags for the transition sub-steps and an improved visual effect at the protruding region A, ultimately leading to a further improved visual effect at the edge of the display panel.

The light-emitting sub-region of any two neighboring edge pixel units 3 in the protruding region can optionally be configured to have a same area difference, which can result in a smoothened transition among neighboring sub-steps in the protruding region. It is noted that the light-emitting sub-region of individual edge pixel unit 3 in the protruding region can be adjusted depending on the edge of the display panel.

FIG. 6 is a schematic diagram of a protruding region after improvement over the protruding region as shown in FIG. 3 by means of a third embodiment of the disclosure. Compared with the first and the second embodiment as respectively shown in FIGS. 4 and 5, whose pixels 4 included in each edge pixel unit in the protruding region both have a rectangular light-emitting sub-region, the pixels 4 included in each edge pixel unit in a protruding region can have a light-emitting sub-region shaped as a right trapezoid, as shown in FIG. 6.

Specifically, as shown in FIG. 6, each sub-pixel 4 has a rectangular shape, and the light-shielding sub-pattern 6 has a shape of a right trapezoid, whose right angle leg aligns with the side of the sub-pixel 4 that is next to the light-shielding region 1, whose slanted leg is parallel with a straight line running across the two ends of the protruding step.

In this embodiment, because the light-shielding sub-pattern 6 is configured to be shaped as a right trapezoid, the light-emitting sub-region of individual sub-pixel 4 also takes a shape of a right trapezoid, which can effectively weaken the appearance of zigzags among the transition sub-steps, causing a more smoothened transition between neighboring sub-steps, ultimately leading to an improved visual effect in the protruding region.

It is noted that the embodiment as shown in FIG. 6, where each of the light-shielding sub-patterns 6 is shaped as a right trapezoid so as to allow its intersection line with its corresponding sub-pixel (i.e. slanted leg) to be parallel with a straight line running across the two sides of the protruding step, represents one preferred embodiment of this disclosure. In some other embodiments, it is only required that the intersection line between the light-shielding sub-pattern and its corresponding pixel has a substantially same ascending direction as the protruding step, which shall be able to weaken or reduce the appearance of zigzags to some extent. The intersection line can be a concave arc or a convex arc.

In some embodiments, the light-shielding region 1 can optionally comprise a second light-shielding pattern (not shown in figures), which is disposed in a same layer along as the first light-shielding pattern 5. The second light-shielding pattern can be made by a conventional display substrate fabrication process, which requires modification of the masks for making the second light-shielding pattern.

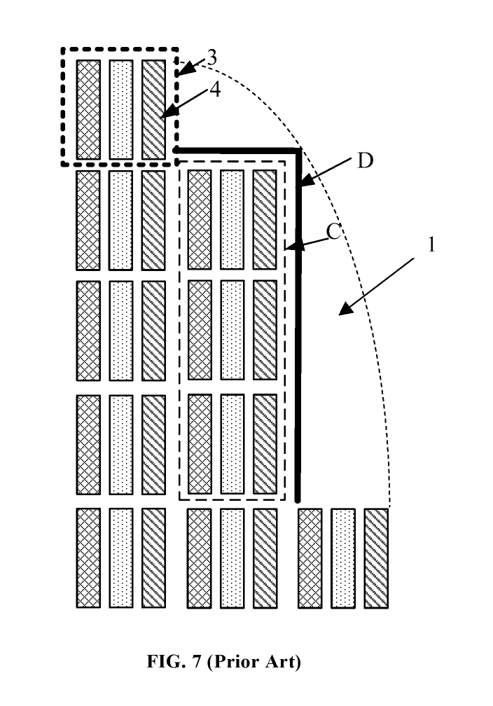

FIG. 7 is a schematic diagram of a protruding region formed by a same column of multiple consecutively aligned edge pixel units in a conventional special-shaped display panel. As shown in FIG. 7, the three consecutive edge pixel units aligned in a same column form a protruding region C; a protruding step D is formed at the intersection between the light-shielding region 1 and the protruding region C; and the protruding step D has a leftward ascending direction.

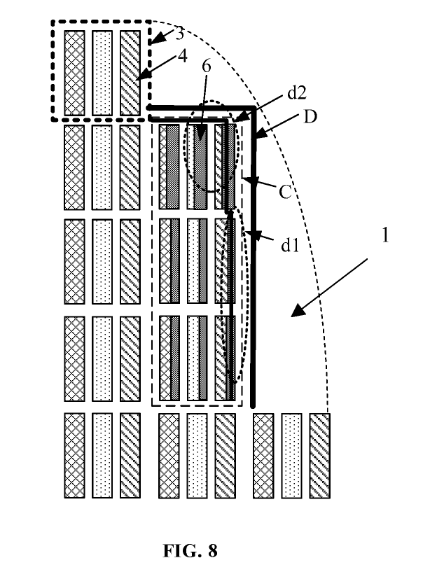

FIG. 8 is a schematic diagram of a protruding region after improvement over the protruding region as shown in FIG. 7 by means of a first embodiment of the disclosure. As shown in FIG. 7, by arranging a first light-shielding pattern 5 in the protruding region C, two transition sub-steps d1 and d2 are formed at the intersection between the light-emitting sub-region of the protruding region C and the first light-shielding pattern 5; and the two transition sub-steps b1 and b2 both have a leftward ascending direction.

Compared with the protruding step D, the two transition sub-steps d1 and d2 are relatively smaller in size and are thus less obvious. Additionally because the two transition sub-steps d1 and d2 both have leftward ascending directions, the transition among different sub-steps appears relatively smooth, and the overall appearance of zigzags at the protruding region C is thus weakened, which ultimately leads to an improved visual effect at the protruding region C. Consequently for the overall display panel, the visual effect at the edge of the display panel is improved.

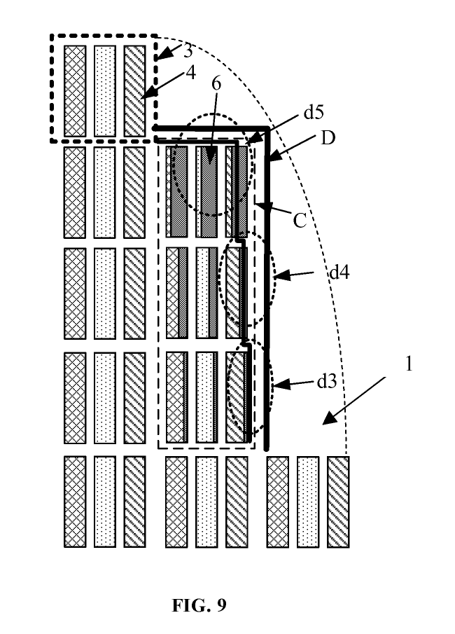

FIG. 9 is a schematic diagram of a protruding region after improvement over the protruding region as shown in FIG. 7 by means of a second embodiment of the disclosure. As shown in FIG. 9, the transition sub-steps d3, d4 and d5 are configured to have a same number as the edge pixel units 3 in the protruding region C, and to correspond to the edge pixel units 3 in a one-to-one relationship. By this configuration, the transition sub-steps d3, d4, and d5 in the protruding region C have an smaller size, thus resulting in a further weakened appearance of zigzags for the transition sub-steps and an improved visual effect at the protruding region C, ultimately leading to a further improved visual effect at the edge of the display panel.

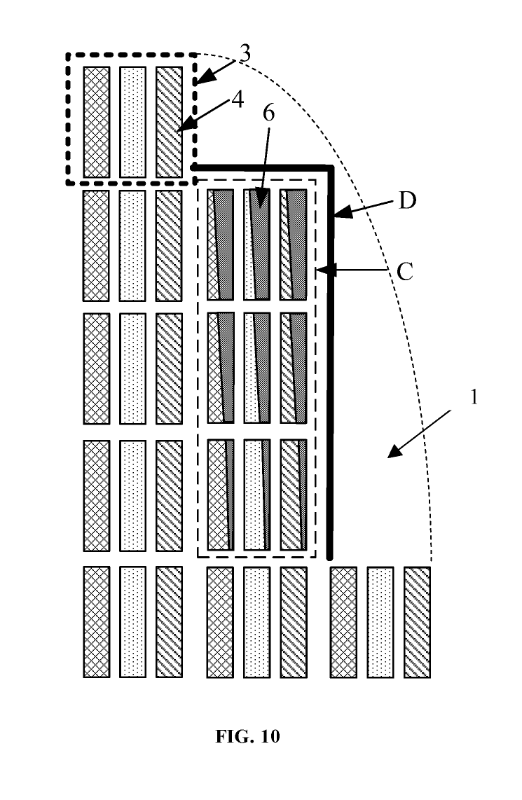

FIG. 10 is a schematic diagram of a protruding region after improvement over the protruding region as shown in FIG. 7 by means of a third embodiment of the disclosure. As shown in FIG. 10, each of the pixels 4 included in an edge pixel unit 3 in the protruding region C has a light-emitting sub-region shaped as a right trapezoid. Specifically, each sub-pixel 4 has a rectangular shape, and the light-shielding sub-pattern 6 has a shape of a right trapezoid, whose right angle leg aligns with the side of the sub-pixel 4 that is next to the light-shielding region 1, whose slanted leg is parallel with a straight line running across the two sides of the protruding step.

In this embodiment, because the light-shielding sub-pattern 6 is configured to be shaped as a right trapezoid, the light-emitting sub-region in individual sub-pixel 4 also takes a shape of a right trapezoid, which can effectively weaken the appearance of zigzags among the transition sub-steps, resulting in a more smoothened transition among neighboring sub-steps and ultimately leading to an improved visual effect in the protruding region.

It is noted that in order to avoid the issue of color difference among different edge pixel units, the pixels 4 in each individual edge pixel unit 3 can each be configured to have a same area for the light-emitting sub-region.

The embodiments as described above can effectively weaken the appearance of zigzags in both the horizontal protruding regions (comprising multiple consecutively aligned edge pixel units on same rows) and the longitudinal protruding regions (comprising multiple consecutively aligned edge pixel units on same columns), leading to an improved visual effect at the edge of display panels.

It is noted that the above embodiments, where the protruding region comprises three edge pixel units 3, are only for illustration and shall not limit the scope of the disclosure. The number of edge pixel units 3 in a protruding region can be an integer >1.

The display substrate can be a color film substrate in some embodiments, a color filter on array (COA) substrate in some other embodiments, or an organic light emitting display (OLED) substrate in yet some other embodiments. The first light-shielding pattern and the second light-shielding pattern can be disposed at a same layer as the black matrix (BM) in the substrate of the color film substrate or the color filter on array (COA) substrate.

In another aspect, the disclosure also provides a display panel, which includes the display substrate as described above.

In yet another aspect, the disclosure also provides a display apparatus, which includes the display panel as described above.

Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A display substrate, comprising a display region, wherein:
the display region has an irregular edge portion including a plurality of edge pixel units, adjacent to a light-shielding region; and
the plurality of edge pixel units have gradually varying light transmission rates along the irregular edge portion.

2. The display substrate of claim 1, wherein:
the display region is provided with a pixel unit array, comprising a plurality of pixel units arranged in rows and columns, wherein each pixel unit comprises at least one pixel; and
the irregular edge portion of the display region comprises at least one protruding region, each of the at least one protruding region comprising a second plurality of edge pixel units, wherein:
the second plurality of edge pixel units are consecutively aligned in a same row or a same column of the pixel unit array, and have gradually varying light transmission rates along the each of the at least one protruding region to thereby reduce a zigzag pattern.

3. The display substrate of claim 2, wherein the second plurality of edge pixel units have gradually varying opening ratios to realize the gradually varying light transmission rates along the each of the at least one protruding region.

4. The display substrate of claim 3, wherein the opening ratios for different pixels of different colors are substantially same within each of the second plurality of edge pixel unit in the each of the at least one protruding region.

5. The display substrate of claim 3, wherein the gradually varying opening ratios for the second plurality of edge pixel units in the each of the at least one protruding region is realized by configuring at least two transition sub-steps between a light-emitting sub-region of the each of the at least one protruding region and the light-shielding region, wherein the at least two transition sub-steps each has a substantially same ascending direction as a protruding step formed between the each of the at least one protruding region and the light-shielding region.

6. The display substrate of claim 5, wherein the light-shielding region comprises at least one light-shielding pattern, disposed over each of the at least one protruding region and configured to form the at least two transition sub-steps in the each of the at least one protruding region.

7. The display substrate of claim 6, wherein the second plurality of edge pixel units in each of the at least one protruding region correspond to the at least two transition sub-steps in a one-to-one relationship.

8. The display substrate of claim 7, wherein any two neighboring edge pixel units in each of the at least one protruding region have a substantially same difference in light-emitting area.

9. The display substrate of claim 6, wherein the at least one light-shielding pattern comprises two light-shielding patterns, and the two light-shielding patterns are disposed in a same layer.

10. The display substrate of claim 6, wherein one of the at least one light-shielding pattern comprises a plurality of light-shielding sub-patterns, corresponding to pixels in each of the second plurality of edge pixel units in a one-to-one relationship.

11. The display substrate of claim 10, wherein each pixel has a rectangular shape, and each of the plurality of light-shielding sub-patterns is rectangular.

12. The display substrate of claim 10, wherein an intersection line between each of the plurality of light-shielding sub-patterns and corresponding pixel has a substantially same ascending direction as the protruding step.

13. The display substrate of claim 12, wherein each of the intersection lines between the plurality of light-shielding sub-patterns and corresponding pixels is a straight line or a curved line.

14. The display substrate of claim 13, wherein each of the intersection lines is a straight line.

15. The display substrate of claim 14, wherein each pixel has a rectangular shape, each of the plurality of light-shielding sub-patterns has a shape of a right trapezoid, wherein a slanted leg of the right trapezoid is aligned with the straight line.

16. The display substrate of claim 15, wherein each of the intersection lines is parallel with one another.

17. The display substrate according to claim 1, wherein the display substrate is a color film substrate, a color filter on array (COA) substrate, or an OLED substrate.

18. The display substrate according to claim 17, wherein the at least one light-shielding pattern is disposed at a same layer as a black matrix in the color film substrate or the color filter on array (COA) substrate.

19. A display panel, comprising the display substrate according to claim 1.

20. A display apparatus, comprising the display panel according to claim 19.
